(19) United States
(12) Patent Application Publication
(10) Pub. No.: US 2008/0169568 A1
(43) Pub. Date: Jul. 17, 2008

(54) Structure and method of making interconnect element having metal traces embedded in surface of dielectric

(75) Inventors: Hideki Kotake, Tokyo (JP); Kiyoshi Hyodo, Tokyo (JP); Inetaro Kurosawa, Tokyo (JP); Yukio Hashimoto, Tokyo (JP); Toku Yoshino, Tokyo (JP); Tomoo Iijima, Tokyo (JP)

Correspondence Address: TESSERA;LERNER DAVID et al., 600 SOUTH AVENUE WEST, WESTFIELD, NJ, 07090, US

(73) Assignee: Tessera Interconnect Materials, Inc., San Jose, CA (US)

(21) Appl. No.: 11/897,200

(22) Filed: Aug. 29, 2007

Related U.S. Application Data
(63) Continuation of application No. 11/643,724, filed on Dec. 21, 2006, now abandoned.
Application No. 11/643,724 is a continuation of application No. 11/410,388, filed on Apr. 25, 2006, now abandoned.
Application No. 11/410,388 is a continuation of application No. 11/246,402, filed on Oct. 6, 2005, now abandoned.

(30) Foreign Application Priority Data
Oct. 6, 2004 (JP) 2004-294260

(51) Int. Cl. H01L 21/768; H01L 23/538

(52) U.S. Cl. 257/773; 438/618; 257/E23.169; 257/E21.576

(57) ABSTRACT

A multilayer interconnect element is provided which includes at least one dielectric element in which metal interconnect patterns are exposed at an outer surface thereof, the metal interconnect patterns having outer surfaces which are co-planar with an exposed outer surface of the dielectric element. In addition, multilayer interconnect elements are provided in which second interconnect elements which do not have co-planar interconnect patterns are integrated therewith as intermediate elements, and the resulting multilayer interconnect element has co-planar interconnect patterns.

### CROSS-REFERENCE TO RELATED APPLICATIONS

This application is a continuation of U.S. patent application Ser. No. 11/643,724, filed Dec. 21, 2006, which is a continuation of U.S. patent application Ser. No. 11/410,388, filed Apr. 25, 2006, which is a continuation of U.S. patent application Ser. No. 11/246,402 filed Oct. 6, 2005, the disclosure of which is hereby incorporated by reference, which is based upon and claims the benefit of priority from Japanese Patent Application No. 2004-294260, filed Oct. 6, 2004, the entire contents of which is incorporated herein by reference.

### BACKGROUND OF THE INVENTION

The present invention specifically relates to interconnect structures for microelectronics, e.g., in the packaging of microelectronic units such as integrated circuits (“ICS” or “chips”) and other interconnect structures, e.g., circuit panels such as includes printed or other types of wiring boards.

In some multi-layer wiring boards, a heat-curable resin such as an epoxy resin is used as an insulator within each wiring level. Interconnections are patterned after a curing reaction performed while the cured substrate is held tightly in a fixture. In this way, interconnections do not twist or break as a result of joining the wiring levels and insulators together in one multilayer board.

Unfortunately, when wiring levels of a multilayer wiring board are insulated by a thermoplastic, presently available methods produce unsatisfactory results. The thermoplastic insulators of each level are joined at temperatures near the melting point of the thermoplastic resin. This causes the metal interconnects within such multilayer wiring boards to twist, short with adjacent interconnections, break, or the like.

In such boards, because the metal interconnect layer protrudes above the surface of each interlayer insulation layer, there was a tendency to have indentations and protrusions on the surfaces of the wiring board layers that make up the multilayer wiring board. When multilayer wiring boards are produced through joining together a plurality of these wiring board layers, the greater the number of layers, the larger the indentations and protrusions on the surface of the multilayer wiring boards. Given this, as wiring boards, the interconnection patterns could become distorted, the adjacent interconnections could short to each other, interconnections could break, and the like, producing fatal defects. In addition, electronic components mounted to such multilayer wiring boards, such as semiconductor integrated circuits, large-scale integrated circuits, and the like, in particular, have large numbers of small terminals. Accordingly, it is highly desirable to maintain the planarity of each set of metal interconnects on an interconnect element or multilayer wiring board. In some cases, large deviations from planarity of the surface of interconnect element on which electronic components such as a chip is mounted is an impediment to high-reliability mounting.

Consequently, excessive indentations and protrusions on the surface of a multilayer wiring board causes problems that cannot be ignored, and thus must be eliminated.

Secondly, given the conventional technology described above, the production of a single multilayer wiring board can require layering process in which one wiring board is joined to another wiring board and in which another wiring board is then joined to the layered unit produced by the prior joining process. This process would then be repeated multiple times, resulting in many manufacturing steps for the multilayer wiring board, making reductions in manufacturing costs difficult.

### SUMMARY OF THE INVENTION

A multilayer interconnect element is provided which includes at least one dielectric element in which metal interconnect patterns are exposed at an outer surface thereof, the metal interconnect patterns having outer surfaces which are co-planar with an exposed outer surface of the dielectric element. In addition, multilayer interconnect elements are provided in which second interconnect elements which do not have co-planar interconnect patterns are integrated therewith as intermediate elements, and the resulting multilayer interconnect element has co-planar interconnect patterns.

According to an aspect of the invention, a multilayer interconnect element is provided which includes a dielectric element having a first major surface, a second major surface remote from the first major surface, a plurality of first recesses extending inwardly from the first major surface and a plurality of second recesses extending inwardly from the second major surface. A plurality of first metal interconnect patterns are embedded in the plurality of first recesses, the plurality of first metal interconnect patterns having outer surfaces which are substantially co-planar with the first major surface and having inner surfaces remote from the outer surfaces. A plurality of second metal interconnect patterns are embedded in the plurality of second recesses. The plurality of second metal interconnect patterns have outer surfaces which are substantially co-planar with the second major surface and inner surfaces remote therefrom. A plurality of solid metal posts conductive connecting the inner surfaces of the plurality of first metal interconnect patterns to the inner surfaces of the plurality of second metal interconnect patterns.

According to another aspect of the invention, a multilayer interconnect element is provided which has a top major surface and a bottom major surface remote from the top major surface. The multilayer interconnect element includes a first interconnect element and a second interconnect element joined thereto. The first interconnect element includes a first dielectric element having a first major surface exposed at the top major surface, a second major surface remote from the first major surface, and a plurality of first recesses extending inwardly from the first major surface. A plurality of first metal interconnect patterns are embedded in the plurality of first recesses, the plurality of first metal interconnect patterns having outer surfaces substantially co-planar with the first major surface, the plurality of first metal interconnect patterns further having inner surfaces remote from the outer surfaces. The first interconnect element further includes a plurality of solid metal posts conductively contacting and extending from the inner surfaces of the first metal interconnect patterns towards the second major surface of the first dielectric element.

The second interconnect element includes a plurality of second metal interconnect patterns that are in conductive communication with the plurality of first metal interconnect patterns. The plurality of second metal interconnect patterns have outer surfaces exposed at the bottom surface of the multilayer interconnect element, the outer surfaces being co-planar with a dielectric element that is exposed at the bottom surface, that dielectric element being either the first dielectric element or another (second) dielectric element other than the first dielectric element.

According to one or more preferred aspects of the invention, the multilayer interconnect element may further include one or more intermediate interconnect elements each including at least one intermediate dielectric element, and at least a plurality of intermediate metal interconnect patterns, the one or more intermediate interconnect elements being disposed between the first and second interconnect elements and providing conductive interconnection between the first and second interconnect elements.

According to one or more preferred aspects of the invention, each of the one or more intermediate interconnect elements includes a plurality of metal posts extending from the plurality of intermediate metal interconnect patterns through the at least one intermediate dielectric element.

According to one or more preferred aspects of the invention, the plurality of metal interconnect patterns of the one or more intermediate interconnect elements have exposed surfaces which are not co-planar with exposed surfaces of the at least one intermediate dielectric element.

According to another aspect of the invention, a method is provided for fabricating an interconnection element. Such method includes providing structure including a first metal layer overlying a second metal layer. A plurality of metal interconnect patterns are patterned from the first metal layer. A plurality of solid metal posts are provided in conductive communication with at least some of the plurality of metal interconnect patterns. A dielectric element is provided which overlies the structure, the dielectric element providing insulation between the plurality of metal posts. The second metal layer is removed selectively to the plurality of metal interconnect patterns to provide the interconnection element having the plurality of metal interconnect patterns embedded in the dielectric element.

According to one or more preferred aspects of the invention, the plurality of metal interconnect patterns have outer surfaces, the outer surfaces being co-planar with a first major surface of the dielectric element.

According to one or more preferred aspects of the invention, the step of forming the dielectric element includes pressing a layer including an uncured resin onto the plurality of metal posts and the plurality of metal interconnect patterns.

According to one or more preferred aspects of the invention, the uncured resin of the dielectric element is cured after pressing the dielectric element onto the plurality of metal posts.

According to one or more preferred aspects of the invention, the plurality of metal posts are formed by forming a mask layer overlying the plurality of metal interconnect patterns, at least some of the plurality of metal interconnect patterns being exposed within openings in the mask layer. A metal is then selectively plated onto the at least some of the plurality of metal interconnect patterns.

According to one or more preferred aspects of the invention, the plurality of metal interconnect patterns includes a plurality of first metal interconnect patterns and the dielectric element includes a second major surface remote from the first major surface. According to such aspect, such method further includes providing a plurality of second metal interconnect patterns in conductive communication with the plurality of solid metal posts, the plurality of second metal interconnect patterns having outer surfaces substantially co-planar with the second major surface of the dielectric element.

According to yet another aspect of the invention, a method is provided for making a multilayer interconnect element which has an exposed dielectric element and exposed metal interconnect patterns. In such interconnect element, the metal interconnect patterns have outer surfaces which are substantially co-planar with the dielectric element.

Such method includes providing a first interconnect element including at least one dielectric layer, at least one interconnect layer including a plurality of raised metal interconnect patterns overlying the dielectric layer and a plurality of interlayer conductors extending from the plurality of raised metal interconnect patterns through the at least one dielectric layer.

Such method further includes providing a second interconnect element having an exposed dielectric element and a plurality of exposed metal interconnect patterns having outer surfaces substantially co-planar with the exposed dielectric element, the second interconnect element including a plurality of metal posts extending from inner surfaces of the plurality of metal interconnect patterns through the exposed dielectric element.

The first interconnect element is joined to the second interconnect element such that the plurality of metal posts conductively interconnect the exposed metal interconnect patterns to the raised metal interconnect patterns and the exposed dielectric element overlies the dielectric layer of the first interconnect element.

### BRIEF DESCRIPTION OF THE DRAWINGS

FIGS. 1(A) through (K) are cross sectional diagrams of series of processes (A) through (K) according to a first embodiment of the present invention.

FIGS. 2(L) through (M) are cross sectional diagrams of a series of processes (L) through (M) according to the first embodiment of the present invention.

FIGS. 3 A) through (H) are cross sectional diagrams illustrating a process according to a second embodiment of the present invention.

FIGS. 4(I) through (M) are cross sectional diagrams further illustrating a process according to the second embodiment of the present invention.

FIGS. 5(H) through (K) are cross-sectional diagrams illustrating a process according to a variation of the second embodiment of the present invention.

FIGS. 6(A) through (D) are cross-sectional diagrams illustrating a series of processes in a third embodiment according to the present invention.

FIGS. 7(A) through (H) are cross-sectional diagrams illustrating a series of processes in a method for manufacturing an interconnect element for an outermost layer according to a fourth embodiment of the present invention.

FIGS. 8(A) through (H) are cross-sectional diagrams showing the series of processes for processing a core wiring board, for integrating interconnect elements for outermost layers with this core wiring board, and for finishing a wiring board through processing the interconnect elements for outermost layers, according to such fourth embodiment.

FIGS. 9(A) through (I) are cross-sectional diagrams showing a series of processes in a fifth embodiment according to the present invention.

FIGS. 10(A) through (H) are cross-sectional diagrams showing a series of processes in a sixth embodiment according to the present invention.

### DETAILED DESCRIPTION

According to certain embodiments of the invention, a multilayer interconnect element or multilayer wiring board is provided wherein metal traces of an interconnection layer are embedded within recesses at the surface of a dielectric element. In addition, the metal traces are formed in such manner that they are much less prone to become twisted, or produce shorts with adjacent interconnections, or break, even when the number of interconnect elements joined together is high. In such embodiments, the surface of each interconnect element presents a substantially planar major surface having conductive contacts thereon for interconnection with other microelectronic elements. In this way, the metal traces do not protrude in ways which interfere with mounting electronic components. Also, improved reliability of the electrical connections may be achieved between several interconnect elements that make up a multilayer interconnect element or multilayer wiring board having three or more layers on which such embedded metal traces are provided. In addition, it may be possible to achieve a reduction in the manufacturing processes required to fabricate such interconnect elements.

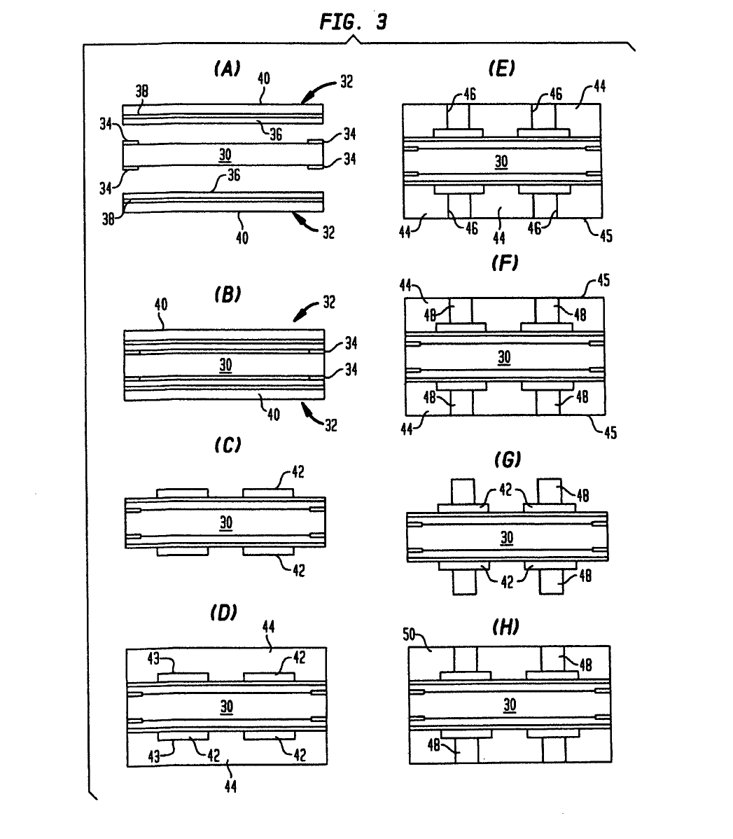

In an interconnect element 22 according to an embodiment of the present invention shown in FIG. 2(M), a dielectric element 20, preferably includes one or more thermoplastic resins or consists essentially of one or more thermoplastic resins, where, for example, PEEK (polyether ether ketone) resin, PES resin, PPS (polyphenylene sulfide) resin, PEN (polyethylene napthalate) resin, a PEEK-PES resin polymer blend, and liquid crystal polymers are specific examples of preferred resins. The thickness of the dielectric element is preferably between several dozen and several hundred microns.

Embedded within the dielectric element 20 are first interconnection patterns 12, 12a provided as a first metal wiring layer and second interconnection patterns 13, 13a provided by a second metal wiring layer. Each of the first interconnect patterns and the second interconnect patterns includes a plurality of metal traces and contacts or other metallic interconnect features. The thickness of each metal wiring layer is preferably between about 10 microns and several dozen microns. The contacts and metal traces function to provide conductive interconnection between the interconnect element 22 and other microelectronic elements external thereto and/or between different external microelectronic elements. Such microelectronic elements can be, for example, any of microelectronic substrates, circuit panels, integrated circuits (“ICs” or “chips”), packaged chips, i.e., chips having package elements bonded thereto, whether or not such chips include only active circuit elements, passive circuit elements such as commonly known as “integrated passives on chip” (IPOC) or chips having a combination of active and passive types of circuit elements, among others.

A plurality of solid metal posts 18 extend through the dielectric element 20 between the first interconnect patterns 12 and the second interconnect patterns 13. The posts most preferably include or consist essentially of copper. Preferably the posts include high purity copper. The end-to-end length or “height” of each post within the dielectric element 20 is preferably between, for example, several dozen and about 150 microns. However, the height may be somewhat greater than or less than the stated preferred range.

In a particular embodiment a chip, circuit panel or packaged chip is directly or indirectly conductively interconnected to or bonded to interconnection patterns 12, 12a including traces and contacts exposed at a first major surface 24 of the interconnect element 22. On a second major surface 26 of the interconnect element 22 remote from the first major surface 24, contacts 13, 13a of the interconnect element can be further bonded, directly or indirectly, to a circuit panel, another chip, or package element of another packaged chip. In another embodiment, the metal traces on one or both major surfaces 24, 26 of the interconnect element 22 can be contacted by a packaged chip and maintain conductive communication with the packaged chip under a moderate amount of pressure in which some flexing of the dielectric element 20 may occur as a result of the pressure between the interconnect element and the packaged chip.

In an embodiment of manufacturing a multilayer interconnect element or wiring board, heating to a temperature of, for example, between 150 and 350° C. is suitable, and a pressure between 20 and 100 kg/cm² is preferred. In addition, it is preferable to coat the metal traces exposed at one or both of the first and second major surfaces 24, 26 with a bond metal, especially when electronic components are to be mounted thereto such as integrated circuits (ICs or chips) that have high numbers of terminals with minute pitches. Gold is well suited for use as the bond metal layer 10.

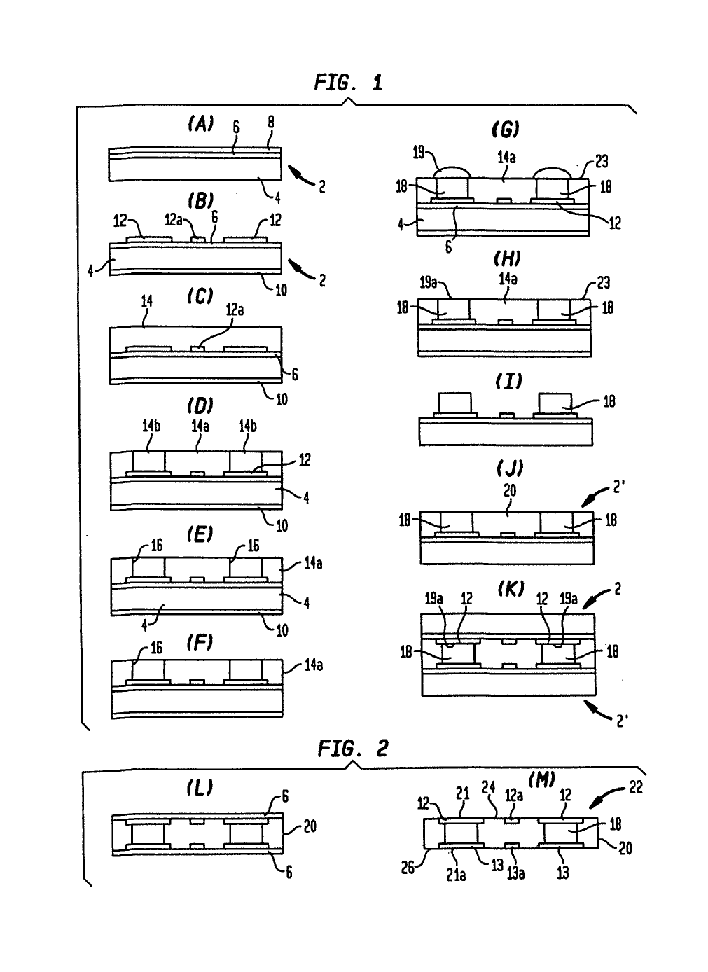

The details of the present invention will be explained based on an embodiment shown in a figure. FIGS. 1(A) through (K) and FIGS. 2(L) through (M) are cross-sectional diagrams showing the sequence of processes (A) through (M) in a first embodiment according to the present invention.

First, a patternable conductive structure 2, made from a three metal layer structure is prepared as shown in FIG. 1(A). The patternable conductive structure 2 has a three-layer structure wherein, for example, an etching barrier layer (an intermediate layer) 6 including or consisting essentially of a metal such as nickel, for example, is fabricated on the surface of a carrier layer 4 made from, for example, copper, and a metal layer 8 for fabricating an interconnection layer made from, for example, copper, is fabricated on the surface of this etching barrier layer 6.

Following this, as shown in FIG. 1(B), a protective layer 10, made from, for example, photoresist, is provided on the surface of the aforementioned carrier layer 4. Layer 10 protects the carrier layer 4 when the metal layer 8 is patterned, e.g., by photolithography and selective etching to form the interconnection patterns 12. Note that 12a indicates the interconnection patterns which are not conductively metal posts or other electrically conductive pillars extending therefrom.

Following this, as shown in FIG. 1(C), a photoresist layer 14 is fabricated on the surface on which the aforementioned interconnection patterns 12, 12a are fabricated.

Following this, as shown in FIG. 1(D), an exposure process is performed on the aforementioned photoresist layer 14. Following exposure, 14a is the exposed portion, and 14b is the non-exposed portion.

Following this, as shown in FIG. 1(E), a developing process is performed. 16 is a hole that is produced by the developing process.

Following this, as shown in FIG. 1(F), preferably, an after-exposure process is performed. Preferably, the exposure dose in this process is larger than the previous exposure dose with respect to FIG. 1(E). The exposed photoresist is then removed, as by a soft etching process, after which ultrasonic rinsing is preferably performed.

Following this, as shown in FIG. 1(G), the aforementioned patterned resist layer 14a is used as a mask to fabricate metal posts 18 or other electrically conductive pillars as vertically rising features that extend upward from the interconnection patterns 12 within the aforementioned holes 16. Preferably, the posts include or consist essentially of one or more metals, for example, copper, preferably formed by plating. This process is performed so that the electrically conductive pillars 18 preferably have a length or height that extends beyond the major surface 23 of the aforementioned resist layer 14a and ends or tops 19 of the pillars 18 protrude above the resist layer 14a.

Following this, referring to FIG. 1(H), a grinding or polishing process is performed until the ends or tops 19a of the aforementioned electrically conductive pillars 18 are co-planar (i.e., are positioned on the same plane as) with the surface of the resist layer 14a. In such way, after processing the tops 19a present flat surfaces.

Following this, as shown in FIG. 1(I) the aforementioned photoresist layer 14a is removed through stripping, or the like and, at the same time, the aforementioned protective layer 10 is also removed from the surface of the carrier layer 4.

Following this, as shown in FIG. 1(J) a dielectric element, an interlayer insulation layer 20 preferably made from a resin is formed through a method such as pressure adhesion, on the surface whereon the aforementioned electrically conductive pillars 18 are formed. In one embodiment, the interlayer insulation layer includes an uncured resin, such layer being provided in form of an epoxy prepreg, for example. Thereafter, the aforementioned interlayer insulation layer 20 is polished or ground until the end surfaces of the aforementioned electrically conductive pillars 18 are exposed. FIG. 1(J) illustrates a planarized condition of the interlayer insulation layer 20 and the posts 18 in a partly formed first interconnect structure 2′ after the grinding process.

Following this, the first such interconnect structure 2′, having an insulating layer 20 is formed in the state shown in FIG. 1(J). In addition, a patternable conductive structure 2 is provided which has exposed interconnect patterns 12, as shown in FIG. 1(B). The two structures 2 and 2′ are then aligned together so that the end surfaces 19a of the metal posts or electrically conductive pillars 18 contact the interconnect patterns 12 of structure 2. Pressure and heat are then applied to join and bond the metal posts 18 to the interconnect patterns of the opposing conductive structure 2. FIG. 1(K) shows the state after this integration.

This joining process connects the metal posts 18 to the interconnect patterns, doing so through metal-to-metal bonding of the posts 18 to the interconnect patterns 13 and 13, especially via copper-to-copper contact. This process integrates the two structures 2 and 2′ into a single unit.

Following this, as shown in FIG. 2(L), the respective carrier layers 4 and 4 (FIG. 1(A)) are removed through, for example, etching.

Following this, as shown in FIG. 2(M), the aforementioned etching barrier layers 6 and 6, made from nickel, are removed through, for example, etching.

Given this type of method for manufacturing, an interconnect element or wiring board is fabricated wherein the interconnection layer and the insulating layer are co-planar as shown in FIG. 2(M), fabricated such that outer surfaces 21 of the interconnect patterns 12 and 12a are co-planar with the first major surface 24 and the outer surfaces 21a of the interconnect patterns 13, 13a are co-planar with the second major surface 26.

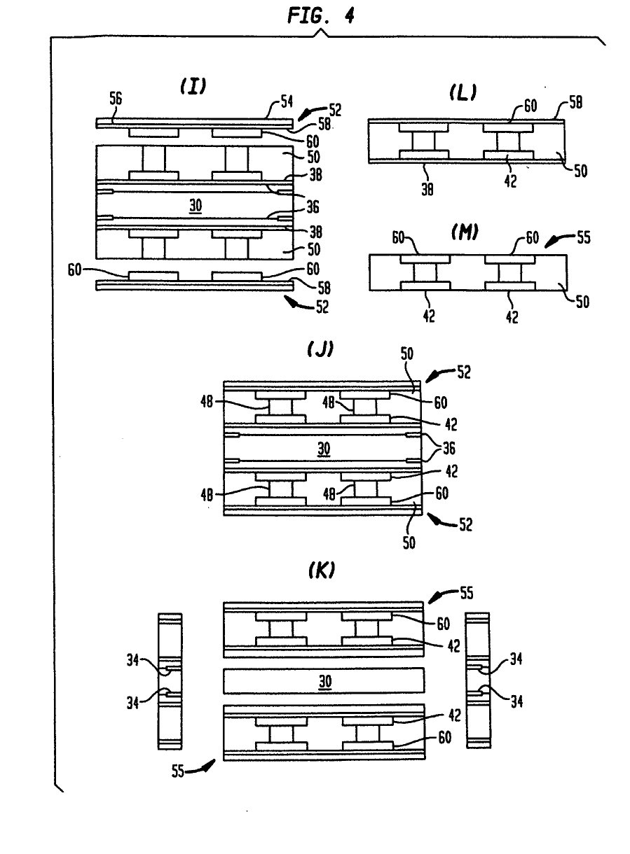

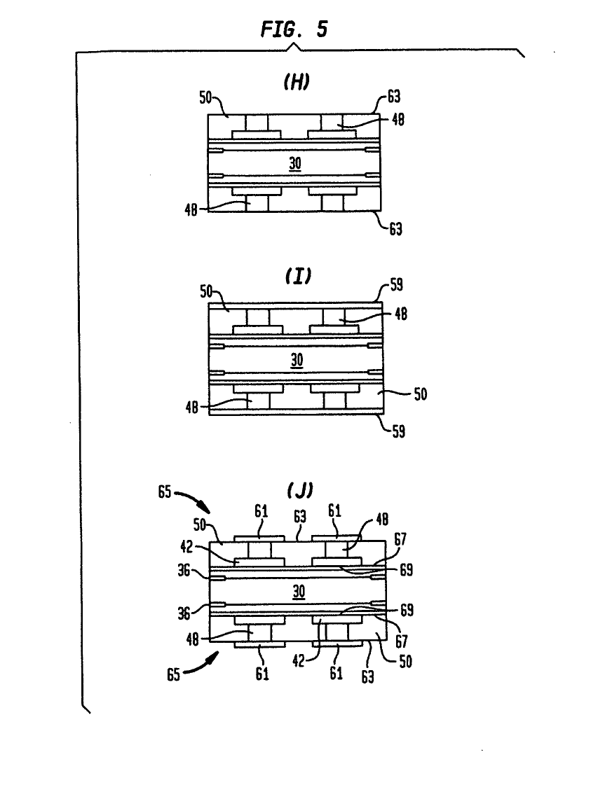

FIGS. 3(A) through (H) and FIGS. 4 (I) through (M) are cross-sectional diagrams showing a series of processes (A) through (M) in a second embodiment according to the present invention.

As shown in FIG. 3(A), two patternable conductive structures 32 and 32, and a core 30, are prepared, the core being made from, for example, a resin. An adhesive sheet 34, made from, for example, a prepreg, or the like, is formed on a part of both sides of this core 30, the prepreg being made from, for example, an epoxy resin. The core 30 will be removed later as being an unneeded area.

Note that each of the aforementioned patternable conductive structures 32 have three-layer structures wherein a metal layer 40 for fabricating an interconnection layer including or consisting essentially of copper, for example, overlies an etching barrier layer (an intermediate layer) 34, which includes or consists essentially of a metal that would not be attacked by an etchant which attacks the first metal. For example, when the first metal includes or consists essentially of copper, and the etching barrier layer can include or consist essentially of nickel. Copper can be etched by an etchant which substantially does not attack nickel. In turn, the first metal 40 and the etching barrier layer 34 are provided on or overlying a surface of a carrier layer 36 made from, for example, copper. The patternable conductive structure is preferably fabricated through rolling, although other methods can be used.

Following this, as shown in FIG. 3(B), the patternable conductive structures 32 and 32 are adhered, through the aforementioned adhesive sheet 34, to both surfaces of the core material 30, such that the metal layer 36 which is the carrier faces the surface of said core material 30. This adhesive sheet 34 is disposed at one or more locations of the patternable conductive structures away from locations where interconnect patterns are to be formed (the active region). Thus, the adhesive sheet 34 is disposed preferably only in an unneeded region.

Following this, as shown in FIG. 3(C), interconnection layers 42 are formed through selectively etching the metal layers 40 of each of the aforementioned patternable conductive structures 32 and 32.

Following this, as is shown in FIG. 3(D), photoresist layers 44 are deposited over surfaces 43 of both of the interconnection layers 42. These resist layers 44 are formed with a thickness that is essentially at the same height as the end surface of the electrically conductive pillars 48 (FIG. 1(F)) to be formed, or with a surface that is slightly lower.

Following this, as is shown in FIG. 3(E), each of the aforementioned resist layers 44 are patterned, such as by photolithography, to form the holes 46.

Following this, as is shown in FIG. 3(F), metal posts 48 or other electrically conductive pillars 48 are fabricated within the holes of the resist layer 44. Preferably, the posts are fabricated by plating with a metal such as copper, for example, using the aforementioned resist layers 44 as masks. The fabrication of these electrically conductive pillars 48 may be performed through overplating, as appropriate, to an extent that the metal posts 48 extend beyond the major surfaces 45 of the interlayer insulation layers 44 such as in the above-described embodiment shown in FIGS. 1(A)-1(K) and FIGS. 2(L)-2(M). Thereafter, grinding or polishing is performed to cause the outer surfaces of the electrically conductive pillars 48 to be co-planar with the major surfaces 45 of the interlayer insulation layer 44.

Following this, as shown in FIG. 3(G), each of the aforementioned resist layers 44 is removed.

Following this, as shown in FIG. 3(H), interlayer insulation layers 50 are formed on each of the surfaces whereon the interconnection layers 42 and the electrically conductive pillars 48 are fabricated. These insulation layers are formed, for example, by a pressure adhesion method, after which the end surfaces of the aforementioned electrically conductive pillars 48 are exposed through grinding the aforementioned interlayer insulation layers 50.

Following this, as shown in FIG. 4(I), interconnect structures 52 and 52 are aligned and overlaid over each of the aforementioned interlayer insulation layers 50 and 50.

Each of the aforementioned interconnection structures 52 and 52 includes an interconnection layer including interconnection patterns 60. The interconnection layer may include or consist essentially of copper, for example. In turn, the interconnection layer overlies an etching barrier layer (an intermediate layer 56), made from, for example, nickel. The etching barrier layer, in turn, overlies a carrier layer 54, made from, for example, copper. Moreover, each of these interconnection structures 52 and 52 are oriented so that the sides whereon the interconnect patterns 60 are formed are facing each of the interlayer insulation layers 50 and 50, and are provided aligned so that the various electrically conductive pillars 48 will be lined up with the corresponding interconnection layers 60.

Following this, as shown in FIG. 4(J), the interconnect structures 52 and 52 are aligned and joined with the aforementioned interlayer insulation layers 50 and 50 through the application of heat and pressure. Consequently, the various electrically conductive pillars 48 integrated, through metal-to-metal bonding, for example, copper-copper bonding, with the corresponding interconnection layers 60. In addition, the interlayer insulation layer 50 becomes joined to the structure 52.

Following this, as shown in FIG. 4(K), that which was integrated in FIG. 4(J) is cut at the part wherein the aforementioned adhesive 34 is adhered, to separate the unneeded core 30 from the active region, the active region being the two interconnect elements 55 each having a first interconnection layer 42 and a second interconnection layer 60 on a side of the interconnect element 55 remote from the first interconnection layer 42.

Following this, the aforementioned carrier layers 54 (FIG. 4(I)) and 36 (FIG. 4(I)) are removed from the interconnect element 55. FIG. 4(L) shows the state after these carrier layers 54 and 36 have been removed.

Following this, each of the aforementioned etching barrier layers 58 and 38 FIG. 4(L) are removed as shown in FIG. 4(M).

This type of method for manufacturing fabricates an interconnect element 55 or a wiring board such as shown in FIG. 4(M) wherein interconnection patterns 60 and 42 are provided as metal patterns embedded in recesses in each of the first and second major surfaces of the interlayer insulation layer 50 so that the outer surfaces of the interconnect patterns and those major surfaces are co-planar.

Furthermore, because the fabrication processes for the two interconnect elements or wiring boards progress simultaneously for both sides until the interconnect elements are separated from the core material 30, this can improve the manufacturing efficiency and can increase the productivity.

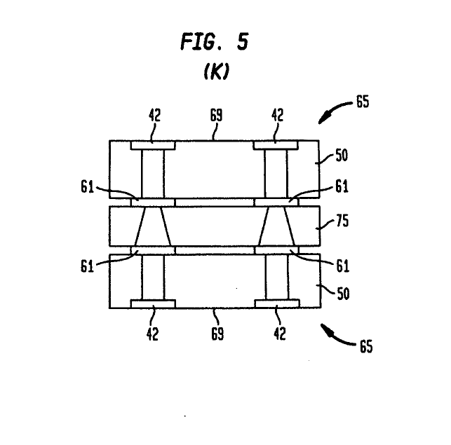

FIGS. 5(H) through (K) are cross-sectional diagrams illustrating the series of processes for simultaneously fabricating two interconnect elements in a variation of the embodiment shown in FIGS. 3(A)-3(H) and FIGS. 4(I)-4(M).

In this embodiment, the same structure as shown in FIG. 3(H) is prepared, according to the processing described above relative to FIGS. 3(A)-3(H). Thereafter, the processes differ from the embodiment described above relative to FIGS. 4(I)-4(M). FIG. 5(H) illustrates the same structure as that shown in FIG. 3(H).

Following this, as shown in FIG. 5(I), metal layers 59 and 59 are provided on opposite sides of the core material 30. The metal layers including or consisting essentially of, for example, copper, are joined, bonded or adhered to the interlayer insulation layers 50 and 50 through the application of heat and pressure. Doing so causes the parts of the metal layers 59 and 59 to form secure connections having excellent conductivity to the metal posts or electrically conductive pillars 48 and 48, because the conductive connections are made through metal-to-metal contact, e.g., copper-copper bonding. In addition, other parts of the metal layers 59 and 59 adhere well to outer surfaces of the interlayer insulation layers 50 and 50.

Following this, as shown in FIG. 5(J) interconnect patterns 61 and 61 are fabricated through patterning, e.g., photolithographically patterning an overlying mask layer and selectively etching the aforementioned metal layers 59 and 59 from within openings in that mask layer.

Following this, in the same manner as shown and described above relative to FIG. 4(K), cutting is performed in the unneeded region part adhered by the adhesive sheet 34, after which the former carrier layers 36 and 36 (FIG. 4(I)) are removed. During such process, the etching barrier layers 38 (FIG. 4(I)) whereon the interconnection layers 61 and 61 are formed are used as masks. Finally, the etching barrier layers 38 can be removed to provide a pair of interconnect elements 65 joined together via adhesive layers 36 and a core 30. These interconnect elements 65 can then be separated from the core as described above relative to FIG. 4(M) to provide a pair of interconnect elements 65 joined together via adhesive layers 36 and a core 30. These interconnect elements 65 can then be separated from the core as described above relative to FIG. 4(K).

When this is done, first interconnect patterns 61, overlying one major surface 63 of the interlayer insulation layer (dielectric element), protrude above the major surface 63 of the interlayer insulation layer 50, as shown in FIG. 5(J). On the other hand, although there are indentations and protrusions on one major surface 63 of the interlayer insulation layer 50, the metal interconnect patterns 42 are embedded in the other major surface 67 of interlayer insulation layer 50 so that outer surfaces 69 of those interconnect patterns 42 are co-planar with that major surface 67. Accordingly, an interconnect element or a wiring board of a double-sided interconnection type is provided.

Following this stage of fabrication, as shown in FIG. 5(K), the interconnect elements 65 can be joined together in a multilayer interconnect element having a different arrangement, e.g., through a central connecting element other than the above-described core 30. In one example, the interconnect elements 65 are joined together through heat and pressure to opposite sides of a dielectric connecting element 75 or “core connector.” Such core connector 75 may or may not have conductive patterns on metallic or conductive posts, vias or metallic connectors extending vertically therethrough. In a particular example, the protruding interconnect patterns 61 face inward, i.e., toward the dielectric connecting element, and the interconnect patterns 42 face outward. In this way, the interconnect patterns 42, which are co-planar with the exposed major surfaces of the dielectric elements 50 face outward. In such case, the aforementioned interconnect element or a wiring board is well suited to manufacturing a multilayer interconnect element 65 or wiring board having embedded interconnect patterns 42 such that it is flat on its outermost surfaces 69.

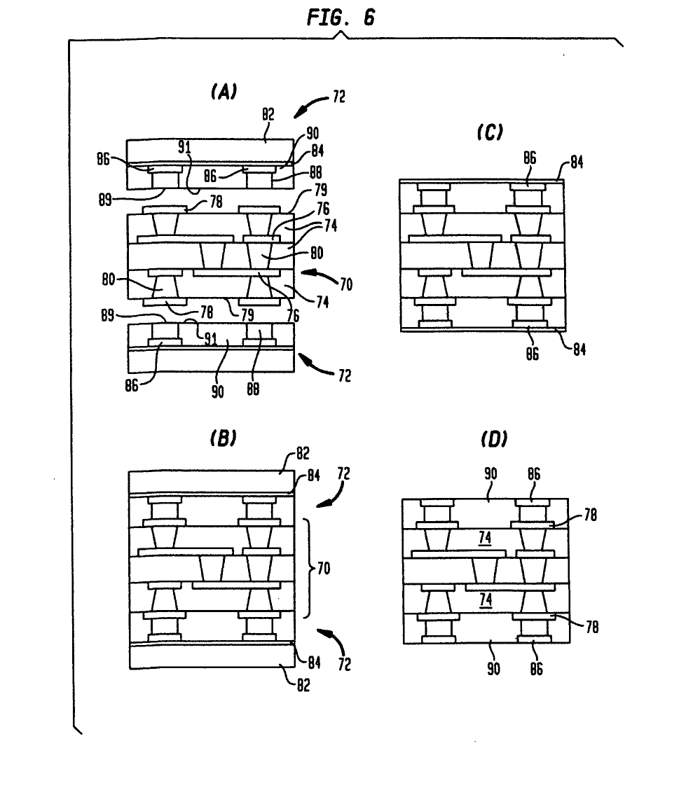

FIGS. 6(A) through (D) are cross-sectional diagrams showing the series of processes in a third embodiment according to the present invention.

As is shown in FIG. 6(A), a core substrate 70, and two outer interconnect elements 72 and 72 are provided which face opposite (front and rear) surfaces of the core substrate 70. The core substrate 70, in the present example, has four interconnect layers, where 74 is an interlayer insulation layer, 76 are inner interconnect patterns 78 are outer interconnect patterns, and 80 is a bump for interlayer connections, where the outer interconnect patterns 78 protrude above the outer major surfaces 79. Thus, the outer (major) surfaces 79 have protrusions and indentations.

Each of the aforementioned outer interconnect elements 72 and 72 includes interconnect patterns 86, which include or consist essentially of a metal such as copper which overlies an etching barrier layer 84. The etching barrier includes or consists essentially of a material such as, for example, nickel, which is not attached by an etchant which attacks the metal from which interconnect patterns 86 are made. The etching barrier layer 84, in turn, overlies a carrier layer 82, preferably including or consisting essentially of copper. A plurality of metal posts or electrically conductive pillars 88, preferably including or consisting essentially a metal such as copper extend from the interconnect patterns 86. An interlayer insulation layer 90 covers an inner surface of the interconnect patterns 86 and fills a space between the electrically conductive pillars 88. End surfaces 89 of the electrically conductive pillars 88 are exposed at an outer surface 91 of the interlayer insulation layer 90.

Furthermore, on both surfaces of the core substrate 70, interconnect elements 72 and 72 are positioned, oriented so that the end surfaces 89 of the electrically conductive pillars 88 and 88 and the outer surface 91 of the interlayer insulation layer 90 are facing the core substrate 70. The interconnect elements and the core substrate are aligned so that each of the electrically conductive pillars 88 and 88 line up with the positions of each of the outer interconnect patterns 78 and 78 of the core substrate 70.

Following this, heat and pressure are applied to join, e.g., bond, adhere or fuse the aforementioned interconnect elements 72 and 72 onto the exposed surfaces of dielectric layers and interconnect patterns 78 of the aforementioned core substrate 70. FIG. 6(B) shows the state after this joining process.

This joining process not only strongly connects the end surfaces of each of the electrically conductive pillars 88 and 88 to the outer interconnect patterns 78 of the core substrate 70 through copper-copper bonding, but also integrates, adheres, bonds or preferably fuses the interlayer insulation layers 74 and 90 to each other.

Following this, as shown in FIG. 6(C), the aforementioned carrier layers 82 and 82 (FIG. 6(B)) are removed through etching, or the like, using, for example, an etchant that etches the material of the carrier layer, e.g., copper, without attacking the material of the etching barrier layer 84, which is preferably nickel.

Following this, the aforementioned etching barrier layers 84 are removed through, for example etching, as shown in FIG. 6(D). When this is done, this can provide a multilayer interconnect element or wiring board having six layers of interconnection layers, where the interconnect patterns of each interconnection layer are co-planar with the outer surfaces of each insulation layer.

This type of method for manufacturing can provide a multilayer interconnect element or wiring board wherein the outermost surfaces are flat and in which interconnect patterns are embedded in and are co-planar with those outermost surfaces. Such method utilizes a core substrate 70 as a base, which has indentations and protrusions on the surfaces thereof, due to the interconnection layers 78. Thereafter, the aforementioned interconnect elements 72 and 72 are aligned and joined thereto so that the electrically conductive pillars 88 and the exposed surfaces 91 of the interlayer insulation layers 90 face inward toward the core substrate 70, and so that the interconnect patterns 86 and 86 face outward.

Note that although in the embodiment described above, the number of layers for the core substrate 70 is four, and the number of layers in the multilayer interconnect element or wiring board produced therefrom is six, this is only a single example. The number of layers in the core substrate 70 is not limited to four, but rather may be a different number of layers, enabling the provision of a multilayer wiring board having a number of layers that is two layers more than the number of layers in the core substrate 70.

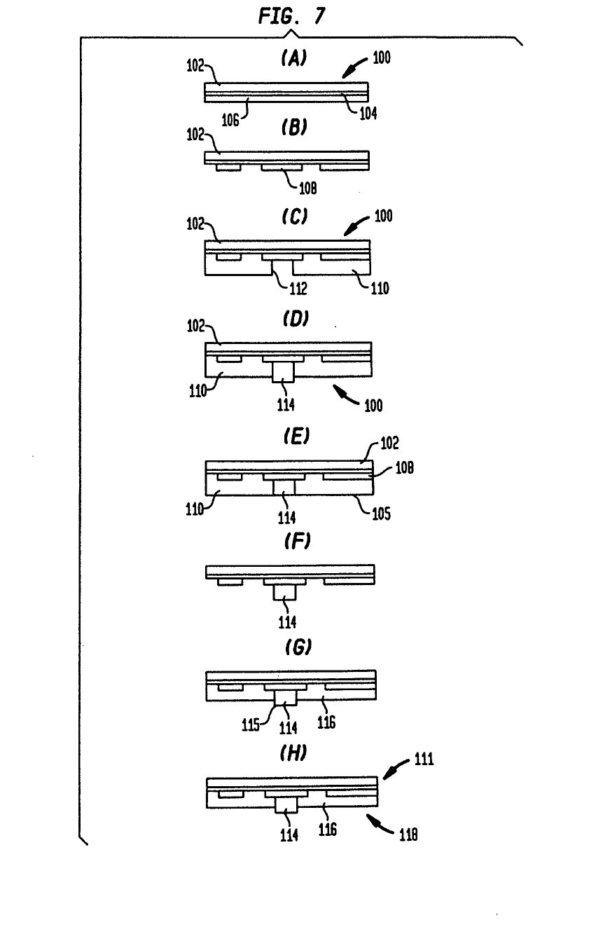

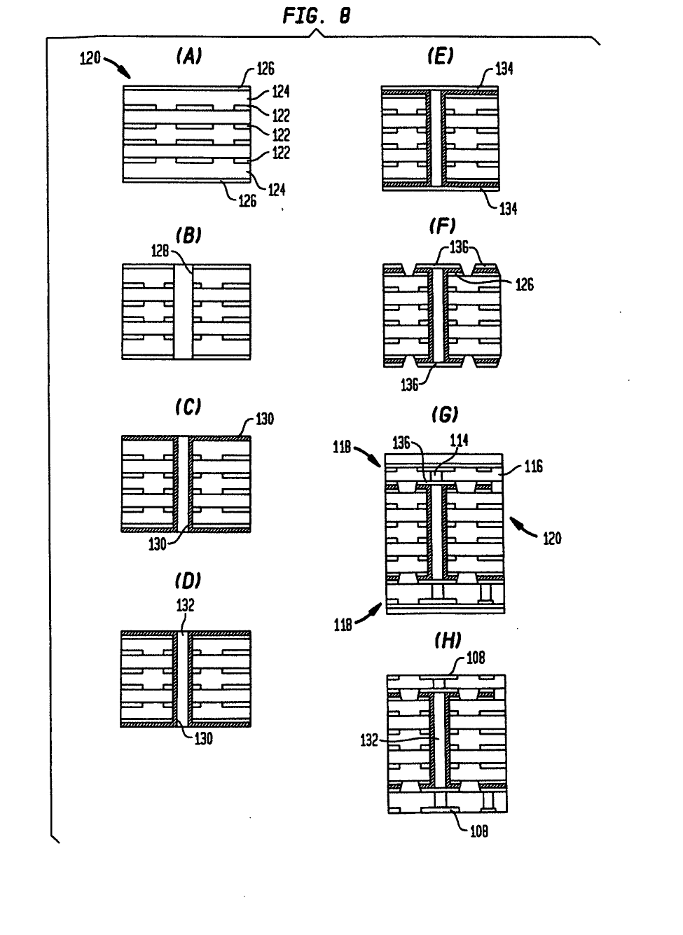

FIGS. 7(A) through (H) and FIGS. 8(A) through (H) are cross-sectional diagrams showing a fourth embodiment according to the present invention. FIGS. 7(A) through (H) illustrate a series of processes for the method of manufacturing an interconnect element 111 (FIG. 7(H)) to be used at outermost layers of a multilayer interconnect element or wiring board. FIGS. 8(A) through (H) illustrate a series of processes for processing a core interconnect element or wiring board for integrating the aforementioned interconnect elements 111 with a core wiring board, and for finishing the multilayer wiring board by further processing the interconnect elements 111.

First, the method for manufacturing the interconnect elements 111 will be explained with reference to FIGS. 7(A) through (H).

As is shown in FIG. 7(A), a three-layer metal structure 100 is prepared in a manner such as described above relative to the structure 2 shown in FIG. 1(A). This three-layer metal structure includes a metal layer 106 to be fabricated into interconnect patterns, made from, for example, copper. Such layer 106 overlies an etching barrier layer 104 made from, for example, nickel, on one surface of a carrier layer 102, made from, for example, copper. The structure 100 may be fabricated through, for example, rolling.

Following this, as is shown in FIG. 7(B), interconnect patterns 108, including traces, contacts, etc., for example, are fabricated through selectively etching the aforementioned metal layer 106 (FIG. 7(A)).

Following this, on the exposed surfaces of the aforementioned interconnect patterns 108, as is shown in FIG. 7(C), a resist layer 110 is deposited and patterned, such as through photolithography. 112 is a hole that is formed in the aforementioned resist layer 110, and a metal post or electrically conductive pillar 114 (FIG. 7(D)), described below, will be formed in this hole 112.

Following this, as shown in FIG. 7(D), the electrically conductive pillar 114 is fabricated preferably by plating a metal such as, for example, copper, using the aforementioned resist layer 110 as a mask. In this case, the electrically conductive pillar 114 is fabricated so as to protrude slightly from the surface of the resist layer 110. This is to make it possible in a subsequent grinding process, to align the tops of the electrically conductive pillars 114 to a specific height, despite variability in the plating process.

Following this, as is shown in FIG. 7(E), the protruding parts of the aforementioned electrically conductive pillars 114 are ground to cause the end surfaces thereof to be co-planar with (i.e., to be on the same plane as) the outer (major) surface 105 of the resist layer 110.

Following this, as is shown in FIG. 7(F), the aforementioned resist layer is removed.

Following this, as is shown in FIG. 7(G), an interlayer insulation layer 116 is provided overlying the aforementioned interconnect patterns 108 and insulating respective ones of the aforementioned electrically conductive pillars 114. After this stage of processing, the tops or ends 115 of the electrically conductive pillars 114 are exposed.

Following this, the ends of the aforementioned electrically conductive pillars 114 are polished or ground to adjust the height and to planarize them to the surface of the interlayer insulation layer 116, to complete the interconnect element 118, as shown in FIG. 7(H).

Note that two of these interconnect elements 118 are prepared, and provided according to the processes shown in FIG. 8(A) through 8(H).

The method for manufacturing to provide a multilayer interconnect element or wiring board according to the present embodiment will be explained next with reference to FIGS. 8(A) through (H).

First, as shown in FIG. 8(A), a core interconnect element or core wiring board 120 is provided.

In this core interconnect element 120, four interconnection layers 122 are provided on the inside thereof, each separated and insulated from others of the layers 122 by interlayer insulation layers 124. Metal layers 126 and 126 are provided on the outermost surfaces.

Following this, as shown in FIG. 8(B), through holes 128 are formed extending from the outermost surfaces through the aforementioned core interconnect element 120.

Following this, as shown in FIG. 8(C), a through hole interconnection layer 130 is fabricated by plating a metal such as copper, for example, using electroless plating or electroplating. The interconnection layer 130 is formed on the surface of the core interconnect element 120, including the surface of the aforementioned through hole 128.

Following this, as shown in FIG. 8(D), the holes on the inside of the aforementioned through hole interconnection layer 130 are filled with an electrically conductive paste or an insulating paste 132, after which the parts of this electrically conductive past or insulating paste 132 protruding at the top and the bottom are polished or ground to eliminate protrusions and indentations.

Following this, a metal layer 134, including or consisting essentially of a metal such as copper, for example, is fabricated on the surface, as shown in FIG. 8(E) by electroless plating and/or electroplating.

Following this, as is shown in FIG. 8(F), an interconnection layer 136 is fabricated through selectively etching the aforementioned metal layer 134 (FIG. 8(E)), the through hole interconnection layer 130, and the metal layer 126.

Following this, as shown in FIG. 8(G), the aforementioned interconnect elements 118 and 118, manufactured using the method shown in FIGS. 7(A)-7(H), are aligned and joined to the exposed surfaces of the aforementioned core substrate 120.

The interconnect elements 118 and 118 are arranged so that the ends of the electrically conductively pillars 114 and the interlayer insulation layers 116 face the exposed surfaces of the interconnection layer 136 of the core interconnect element 120. The interconnect elements are aligned so that each of the electrically conductively pillars 114 are lined up with the interconnection layers 136 corresponding thereto. Thereafter, pressure and heat are applied to bond, adhere or fuse the interconnect elements 118 to the core interconnect element 120.

Following this, the carrier layers 102 and 102 (FIG. 7(A)) of the aforementioned interconnect elements 118 and 118 are removed, following which the etching barrier layers 104 and 104 (FIG. 7(A)) are removed. FIG. 8(H) shows the state after these etching barrier layers have been removed.

This method of manufacturing produces a multilayer interconnect element or wiring board that has through holes for electrical connection between layers thereof and which has flat outer surfaces.

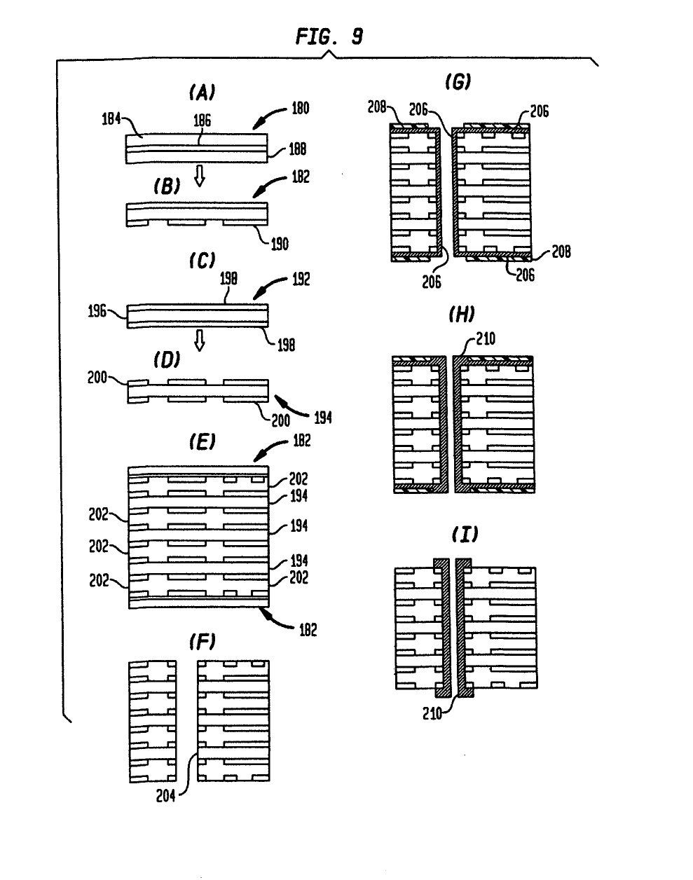

FIGS. 9(A) through (I) are cross-sectional diagrams showing the sequence of processes in a fifth embodiment of the present invention.

First, referring to FIGS. 9(A)-9(B), two interconnect elements used for the outermost layers of the wiring board are prepared. Referring to FIGS. 9(C)-9(D), one or more interconnect elements used for intermediate layers are prepared.

First the interconnect elements 182 (FIG. 9(B)) for the outermost layers are prepared. For ease of reference, only a single interconnect element 182 is shown.

This interconnect element 182 can be made through preparing a three-layer metal structure 180 (FIG. 9(A)) wherein a metal layer 188, including or consisting essentially of a metal such as copper, for example, is provided, overlying an etching barrier layer 186, including or consisting essentially of a metal, which is not attacked by an etchant which attacks the first metal, e.g. copper. The metal of which the etching barrier layer is formed may be nickel, for example. Such layer 186 overlies one surface of a carrier layer 184 including or consisting essentially of a metal, such as copper, for example. The metal layer 188 is patterned, e.g., by photolithographic process to produce an interconnection layer 190 including interconnect patterns such as traces, contacts, etc.

Referring to FIGS. 9(C)-9(D), an interconnect element 194 for an intermediate layer is prepared. Although in FIG. 9(D) only one interconnect element 194 for an intermediate layer is shown, a plurality thereof may be provided. Illustratively, in the present embodiment, three are provided. Each interconnect element 194 for an intermediate layer can be produced through preparing a three-layer structure 192 wherein metal layers 198 are fabricated on both sides of an interlayer insulation layer 196 (FIG. 9(C)), and these metal layers 198 on both sides are then patterned, such as by photolithographic processes.

Following this, a plurality, or in the example as specifically shown, three interconnect elements 194 are stacked with interlayer insulation layers 202 interposed there between, after which the aforementioned interconnect elements for the outermost layers 182 are stacked at specific positions on both outside surfaces of the stack. Thereafter, heat and pressure are applied to join the interconnect elements 182 as outermost layers with the interconnect elements 194 disposed between them to join the components 202, 194, 194, 194, and 202. FIG. 9(E) shows the state after these components have been joined.

Following this, the carrier layers 184 (FIG. 9(A)) are removed from the outermost surfaces of the layered unit that has been integrated as described above, after which the etching barrier layers 186 are removed, following which through holes 204 are provided in specific locations. FIG. 9(F) shows the state after the through holes 204 have been formed.

Following this, a plated underlayer 206, including or consisting essentially of a metal such as copper, for example is fabricated by electroless plating on the surface of the aforementioned layered unit, including the inner peripheral surface of the aforementioned through holes 204, after which a resist layer 208, which will serve as the mask layer for through hole fabrication, is deposited and patterned, e.g. by photolithography. FIG. 9(G) shows the state after the fabrication of this resist layer 208.

Following this, as shown in FIG. 9(H), the aforementioned resist layer 208 is used as a mask to fabricate a through hole interconnection layer 210, including or consisting essentially of a metal such as copper, for example on top of the aforementioned plated underlayer 206. Note that the fact that the inner peripheral surface of the aforementioned through hole interconnection layer 210 may be filled with an electrically conductive paste or an insulating paste 132 is the same as the case of the embodiment shown in FIG. 8(D).

Following this, the aforementioned resist layer 208 (FIG. 9(G) is removed, and the aforementioned plated underlayer 206 is also removed to expose the interconnection layer 190. This can provide a multilayer wiring board that uses the through hole interconnection layer 210 as an interlayer connection means to enable greater levels of integration by allowing a great number of intermediate interconnect elements 195 each having an interconnection layer to be joined and electrically connected together in one multilayer interconnect element.

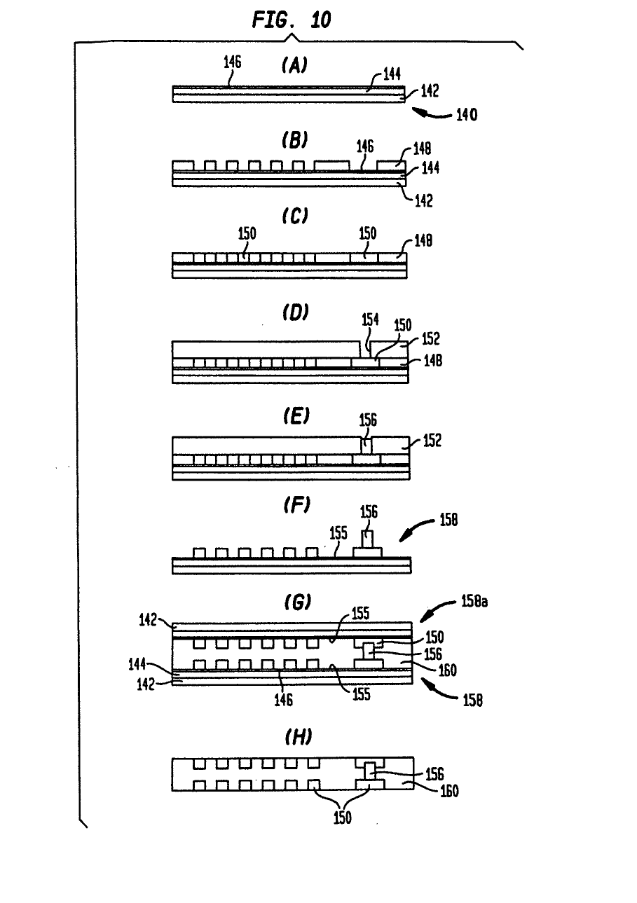

FIGS. 10(A) through (H) are cross-sectional diagrams of a series of processes according to a sixth embodiment of the present invention.

As is shown in FIG. 10(A), a three-layer metal structure 140 is prepared. This three-layer metal structure 140 has a metal underlayer 146, including or consisting essentially of a metal such as copper, for example, layered on top of an etching barrier layer 144 including or consisting essentially of a metal such as nickel, for example. The etching barrier layer in turn overlies a surface of a carrier layer 142, which includes or consists essentially of a metal such as copper, for example. The metal structure 140 may be fabricated through rolling, for example.

Following this, as shown in FIG. 10(B), a first photoresist layer 148 is deposited and patterned over the aforementioned metal structure 140. Following this, as shown in FIG. 10(C), an interconnection layer 150 including metal interconnect patterns, e.g., traces and/or contacts is fabricated through plating a metal, for example, copper, using the aforementioned resist layer 148 as a mask, after which a surface roughening process is performed for roughening the surface of this interconnection layer 150.

Following this, as shown in FIG. 10(D), a second resist layer 152 is deposited and patterned to overlie the first photoresist layer 148. 154 is a hole that is formed in the resist layer 152, where an electrically conductive pillar 156 (FIG. 10(E)) described below, will be formed therein.

Following this, as shown in FIG. 10(E), a metal post or other electrically conductive pillar 156 is fabricated through plating a metal, for example, copper, using as a mask the aforementioned second resist layer 152. These electrically conductive pillars 156 are fabricated on the roughened surface of the interconnection layer 150, enabling excellent adhesion between the interconnection layer 150 and the electrically conductive pillar 156, and enabling excellent contact properties.

Following this, as shown in FIG. 10(F), the aforementioned second resist layer 152 is removed. 158 is an interconnect element that results after removing such layer 152.

Following this, a second interconnect element 158a, structured from the aforementioned interconnect element 158, with the electrically conductive pillars 156 removed from the interconnect element 158 (or, more precisely, a structure wherein the electrically conductive pillars 156 were not fabricated) is provided.

Given this, the surface 155 of the interconnect element 158 from which the electrically conductive pillars 156 and the interconnection layer 150 extend and the surface 155 from which the interconnection layer 150 of the interconnect element 158a extends are disposed facing each other, and aligned so that each of the electrically conductive pillars 156 of interconnect element 158 contacts the corresponding interconnection layer 150 of interconnect element 158a. An interlayer insulation layer 160 is interposed between the interconnect element 158a and the interconnect element 158. In this state, heat and pressure are applied to join, e.g. bond, adhere or fuse the interconnect elements 158a and 158 together. FIG. 10(G) shows the state after this joining process.

Following this, the carrier layers 142 and 142 of the interconnect elements 158 and 158a are removed, after which the etching barrier layers 144 and 144 are also removed. Thereafter, the aforementioned metal underlayers 146 and 146 are also removed.

This provides a multilayer interconnect element or wiring board wherein interconnection layers 150 are fabricated on both surfaces of an interlayer insulation layer 160, co-planar therewith. FIG. 10(H) shows the wiring board that is produced through the removal of the metal underlayers 146 and 146.

The multilayer interconnect elements or wiring boards shown and described in this embodiment are similar to those described above, having a structure in which outermost surfaces of the dielectric elements are flat and interconnect patterns exposed at those surfaces are co-planar thereto.

On the other hand, with reference to FIGS. 10(A) through 10(H) the interconnect elements are aligned and joined together and integrated in a state wherein the surfaces on the ends of the electrically conductive pillars 156 are in contact with the corresponding interconnection layer 150. The aforementioned carrier layers 142 and 142 of each of the aforementioned interconnect elements 158 and 158a, the aforementioned etching barrier layers 144 and 144, and the aforementioned metal underlayers 146 and 146 are removed sequentially.

Referring to FIG. 10(H), while the interconnect element 158 on which the electrically conductive pillars 156 are fabricated, and the interconnect element 158a that is structured without these electrically conductive pillars, are layered with an interlayer insulation layer 160 interposed between them. In a variation of such embodiment, interconnect elements 158 and 158, which have electrically conductive pillars 156 extending therefrom can be joined such that the electrically conductive pillars 156 and 156 contact each other, as integrated within an interlayer insulation layer 160 interposed between the two interconnect elements 158.

As these and other variations and combinations of the features set forth above can be utilized, the foregoing description of the preferred embodiment should be taken by way of illustration rather than by limitation of the invention.

### INDUSTRIAL APPLICABILITY

The present invention can be used in, among others, in interconnect elements, e.g., wiring boards, etc. wherein a plurality of metal traces of an interconnection layer are exposed at one of the surfaces of a dielectric element, e.g., an interlayer insulation layer made from, for example, a resin such as a thermoplastic. Posts or interlayer contact pillars, made from a metal such as, for example, copper extend through such dielectric element. Such posts or pillars can provide interlayer connections corresponding to at least portions of interconnection layers of respective layers of a multilayer wiring boards. In addition, the present invention finds use in methods of making interconnect elements and in methods of manufacturing multilayer wiring boards.

1. A multilayer interconnect element, comprising:
a dielectric element having a first major surface, a second major surface remote from said first major surface, a plurality of first recesses extending inwardly from said first major surface and a plurality of second recesses extending inwardly from said second major surface;
a plurality of first metal interconnect patterns embedded in said plurality of first recesses, said plurality of first metal interconnect patterns having outer surfaces substantially co-planar with said first major surface and inner surfaces remote therefrom;
a plurality of second metal interconnect patterns embedded in said plurality of second recesses, said plurality of second metal interconnect patterns having outer surfaces substantially co-planar with said second major surface and inner surfaces remote therefrom; and
a plurality of solid metal posts conductively connecting said inner surfaces of said plurality of first metal interconnect patterns to said inner surfaces of said plurality of second metal interconnect patterns.

2. A multilayer interconnect element having a top major surface and a bottom major surface remote from said top major surface, said multilayer interconnect element comprising:
a first interconnect element including:
(a) a first dielectric element having a first major surface exposed at said top major surface, a second major surface remote from said first major surface, and a plurality of first recesses extending inwardly from said first major surface,
(b) a plurality of first metal interconnect patterns embedded in said plurality of first recesses, said plurality of first metal interconnect patterns having outer surfaces substantially co-planar with said first major surface, said plurality of first metal interconnect patterns having inner surfaces remote therefrom, and
(c) a plurality of solid metal posts conductively contacting and extending from said inner surfaces of said first metal interconnect patterns towards said second major surface of said first dielectric element; and
a second interconnect element joined to said first interconnect element, said second interconnect element including a plurality of second metal interconnect patterns in conductive communication with said plurality of first metal interconnect patterns, said plurality of second metal interconnect patterns having outer surfaces exposed at said bottom surface of said multilayer interconnect element and co-planar with a dielectric element exposed at said bottom surface, wherein said exposed dielectric element includes at least one of said first dielectric element or a second dielectric element.

3. The multilayer interconnect element as claimed in claim 2, further comprising one or more intermediate interconnect elements each including at least one intermediate dielectric element, and at least a plurality of intermediate metal interconnect patterns, said one or more intermediate interconnect elements being disposed between said first and second interconnect elements and providing conductive interconnection between said first and second interconnect elements.

4. The multilayer interconnect element as claimed in claim 3, wherein each of said one or more intermediate interconnect elements includes a plurality of metal posts extending from said plurality of intermediate metal interconnect patterns through said at least one intermediate dielectric element.

5. The multilayer interconnect element as claimed in claim 4, wherein said plurality of metal interconnect patterns of said one or more intermediate interconnect elements have exposed surfaces which are not co-planar with exposed surfaces of said at least one intermediate dielectric element.

6. A method of fabricating an interconnection element, comprising:
providing structure including a first metal layer overlying a second metal layer;
patterning a plurality of metal interconnect patterns from said first metal layer;
forming a plurality of solid metal posts in conductive communication with at least some of said plurality of metal interconnect patterns;
forming a dielectric element overlying said structure, said dielectric element providing insulation between said plurality of metal posts; and
removing said second metal layer selectively to said plurality of metal interconnect patterns to provide said interconnection element having said plurality of metal interconnect patterns embedded in said dielectric element.

7. The method as claimed in claim 6, wherein said plurality of metal interconnect patterns have outer surfaces, said outer surfaces being co-planar with a first major surface of said dielectric element.

8. The method as claimed in claim 6, wherein said step of forming said dielectric element includes pressing a layer including an uncured resin onto said plurality of metal posts and said plurality of metal interconnect patterns.

9. The method as claimed in claim 8, further comprising curing said uncured resin of said dielectric element after pressing said layer onto said plurality of metal posts.

10. The method as claimed in claim 6, wherein said plurality of metal posts are formed by forming a mask layer overlying said plurality of metal interconnect patterns, at least some of said plurality of metal interconnect patterns exposed within openings in said mask layer, and selectively plating a metal onto said at least some of said plurality of metal interconnect patterns.

11. The method as claimed in claim 6, wherein said plurality of metal interconnect patterns includes a plurality of first metal interconnect patterns and said dielectric element includes a second major surface remote from said first major surface, said method further comprising providing a plurality of second metal interconnect patterns in conductive communication with said plurality of solid metal posts, said plurality of second metal interconnect patterns having outer surfaces substantially co-planar with said second major surface of said dielectric element.

12. A method of making a multilayer interconnect element having an exposed dielectric element and exposed metal interconnect patterns having outer surfaces substantially co-planar therewith, comprising:
providing a first interconnect element including at least one dielectric layer, at least one interconnect layer including a plurality of raised metal interconnect patterns overlying said dielectric layer and a plurality of interlayer conductors extending from said plurality of raised metal interconnect patterns through said at least one dielectric layer;
providing a second interconnect element having an exposed dielectric element and a plurality of exposed metal interconnect patterns having outer surfaces substantially co-planar with said exposed dielectric element, said second interconnect element including a plurality of metal posts extending from inner surfaces of said plurality of metal interconnect patterns through said exposed dielectric element; and
joining said first interconnect element to said second interconnect element such that said plurality of metal posts conductively interconnect said exposed metal interconnect patterns to said raised metal interconnect patterns and said exposed dielectric element overlies said dielectric layer of said first interconnect element.
